(19) United States
(12) Patent Application Publication
(10) Pub. No.: US 2015/0208535 A1
(43) Pub. Date: Jul. 23, 2015

(54) WATERPROOF CONTAINER

(71) Applicant: Da-Chung Wu, Taipei City (TW)

(72) Inventor: Da-Chung Wu, Taipei City (TW)

(21) Appl. No.: 14/161,333

(22) Filed: Jan. 22, 2014

(51) Int. Cl. H05K 5/03

(52) U.S. Cl. CPC H05K 5/03

(57) ABSTRACT

A waterproof container for accommodating a portable electronic device mainly includes a resilient frame, a first housing, a second housing and a plurality of screw members. The resilient frame, mounted around a circumference of the portable electronic device, has a surface to be combined with the first housing and a bottom surface to be combined with the second housing so that a space for accommodating the portable electronic device is formed. Using a frame structure constituted by an integrally formed waterproof resilient material can effectively work with the use of the anti-collision and circumferential function keys of the portable electronic device to enhance the convenience in use and further to possess the high anti-water-pressure capability, integrate and simplify the manufacturing processes and decrease the cost.

### BACKGROUND OF THE INVENTION

(1) Field of the Invention

The invention relates to a waterproof structure, and more particularly to a waterproof container for accommodating a portable electronic device, wherein the waterproof container has a waterproof and resilient main structure, can effectively work in conjunction with the function key or jack of the portable electronic device, and can assist the user in directly operating the portable electronic device in the water.

(2) Description of the Prior Art

With the progress of the technology, the electronic industry has been gradually integrated into and is inseparable from the daily life of the human being in either the work information transmission or the daily message interaction or even the entertainment leisure in the life. The portable electronic devices, such as the frequently seen mobile devices including a smart phone, a tablet computer and the like, have become the media that are carried and used widely by the modern human being.

These portable electronic devices are precise electronic products. In order to ensure the performance and the lifetime, the product is usually avoided to contact the water as possible as it can so that the possibility of the water infiltration can be decreased. Thus, the product cannot be conveniently used in the water-rich environment, such as the seaside environment, the river tracing environment, the swimming pool environment, the rainy environment, the snowy environment or the self-rescue scourge environment. Thus, some waterproof shells applied to the portable electronic device have been available in the market. Each of most of the waterproof shells includes an upper housing and a lower housing combined together, and a simple waterproof structure (typically a gasket disposed in the gap between the combined housings) for covering the portable electronic device. However, such a waterproof shell only has the simple waterproof effect, but has no corresponding structure that enables the user to directly operate the portable electronic device from the outside of the housings, so that the requirement in use cannot be satisfied.

In order to enhance the convenience in use, there is provided a waterproof shell having a waterproof button disposed at a suitable position to assist the user in operating the function key on the circumference of the portable electronic device. In this waterproof shell with this structure, however, an individual waterproof structure has to be provided for each added waterproof button. So, the manufacturing processes are complicated, the production cost is increased, and the simplification of the manufacturing processes and the mass-production requirements cannot be satisfied. Furthermore, the waterproof shell with this structure has multiple independent waterproof structures, and tends to cause the individual seepy problem in the deeper water or when being used in the water for a long time due to different water pressures that may be withstood by different waterproof structures. Thus, the better waterproof effect cannot be achieved.

### SUMMARY OF THE INVENTION

In view of the above-mentioned problems, the invention provides a waterproof container, which can overcome the conventional drawbacks, possess the convenience in use and operation, and further possess the higher anti-water-pressure capability. In addition, using the integrally formed waterproof resilient material to construct the frame structure can effectively simplify the manufacturing processes and decrease the manufacturing cost.

To achieve the above-identified object, the invention provides a waterproof container for accommodating a portable electronic device. The waterproof container includes a resilient frame, a first housing, a second housing and a plurality of screw members. The resilient frame is a polygonal ring, disposed at a horizontal position corresponding to the portable electronic device, and for surrounding a circumference of the portable electronic device. The first housing is disposed above the resilient frame and annularly formed with a first combining portion to be combined with a surface of the resilient frame, and has a plurality of first screwing portions. The second housing is disposed below the resilient frame, is annularly formed with a second combining portion, to be combined with a bottom surface of the resilient frame, and has a plurality of second screwing portions at positions corresponding to the first screwing portions. The screw members screw the corresponding first screwing portions to the corresponding second screwing portions, so that the first housing, the resilient frame and the second housing are combined together, a relative position between the first housing and the second housing is fixed, and the first housing and the second housing can tightly clamp the resilient frame to achieve a waterproof effect.

The top and bottom side surfaces of the resilient frame are tightly combined with the first housing and the second housing to form the strong waterproof property. In addition, the resilient frame mounted around the circumference of the portable electronic device can synchronously have the effects of effectively buffering the impact or press of the external force, and the protection effect can be obtained.

Preferably, the resilient frame further has at least one auxiliary button, which is projectingly formed with a button projection for pushing against a function key on the circumference of the portable electronic device at a position corresponding to an inner surface of the resilient frame. Thus, the user can directly press the auxiliary button from the outside to operate the portable electronic device and enhance the convenience in use.

Preferably, the resilient frame is further projectingly formed with at least one waterproof land surroundingly disposed on the surface or the bottom surface of the resilient frame in a continuous or discontinuous manner. Thus, according to the property of the resilient material of the resilient frame, when the resilient material is combined with the first housing and the second housing, the position of the waterproof land is pressed to form the waterproof structure with the higher density (or high stress), thereby effectively enhancing the ability of resisting the water pressure and the dual waterproof effect.

Preferably, a plurality of through holes is further formed between the surface and the bottom surface of the resilient frame, and the through holes, through which the screw members pass, correspond to the first screwing portions.

Preferably, the through holes are disposed on an outer side of the waterproof land. Thus, the waterproof land can avoid the possible seepage from the screw member, thereby achieving the optimum waterproof effect.

Preferably, the resilient frame may further have another waterproof land surrounding outer sides of the through holes so that the multiple waterproof barriers can be formed.

Preferably, the resilient frame further has a protection edge surroundingly disposed on an outer side of the resilient frame in a continuous or discontinuous manner. Thus, the circumferential impact force can be buffered to obtain the anti-collision effect.

Preferably, the surface of the resilient frame has a first limit structure, and a shape of the first combining portion relatively matches with the first limit structure. Thus, the first housing and the resilient frame may be combined more firmly, and it is possible to effectively prevent the problems that the resilient frame is pressed and deformed and generates the relative displacement.

Preferably, the first limit structure comprises a first limit slot formed between the protection edge and the surface of the resilient frame, and a convex edge or a concave edge of the resilient frame formed at a position corresponding to a function key or a jack on the circumference of the portable electronic device.

Preferably, the bottom surface of the resilient frame is formed with a second limit structure, and a shape of the second combining portion relatively matches with the second limit structure. Thus, the second housing and the resilient frame may be combined more firmly, and the problem of generating the relative displacement can be avoided.

Preferably, the second limit structure comprises a second limit slot formed between the protection edge and the bottom surface of the resilient frame, and the convex edge or the concave edge of the resilient frame formed at the position corresponding to the function key or the jack on the circumference of the portable electronic device.

Preferably, the waterproof container may further comprise at least one waterproof plug for closing an opening or a hole formed on the resilient frame at the position corresponding to the jack on the circumference of portable electronic device. Thus, the user only needs to open the waterproof plug to perform the functions of charging or using the jack without the complicated process of taking out the portable electronic device. More particularly, the user may also use the function of the jack in the water by inserting an insert plug combining with the waterproof plug, so that the convenience in use is significantly enhanced.

Preferably, each of the first limit structure and the second limit structure may further comprise a plurality of limit projections.

Preferably, the first housing further has a transparent panel, which is disposed at a position corresponding to a surface touch screen of the portable electronic device, and for covering the surface touch screen of the portable electronic device when the portable electronic device is accommodated.

Preferably, an inner surface of the resilient frame may be further upwardly or downwardly extended with a buffer pad to assist in fixing the horizontal position of the portable electronic device, to further enhance the ability of buffering the impact of the external force, and to achieve the better protection effect.

Preferably, an inner side of the second housing further has at least one resilient pad for pushing against a backside of the portable electronic device to assist in fixing the vertical position of the portable electronic device, so that the touch screen of the portable electronic device completely pushes against the transparent panel of the first housing and the user can operate the touch screen more smoothly.

Preferably, the downwardly extended buffer pad of the inner surface of the resilient frame may be further inwardly extended to form a resilient pad having top and bottom sides for pushing against a backside of the portable electronic device and the second housing, respectively. Thus, it is possible to assist in fixing the vertical position of the portable electronic device, so that the touch screen of the portable electronic device completely pushes against the transparent panel of the first housing and the user can operate the touch screen more smoothly.

Further aspects, objects, and desirable features of the invention will be better understood from the detailed description and drawings that follow in which various embodiments of the disclosed invention relating to two popular portable electronic devices are illustrated by way of examples.

### BRIEF DESCRIPTION OF THE DRAWINGS

FIG. 1 is a decomposed schematic illustration of a first embodiment of the invention;

FIG. 2 is a decomposed schematic illustration of the first embodiment of the invention at another viewing angle;

FIG. 3 is a pictorial view of a resilient frame of the first embodiment;

FIGS. 3a and 3b are enlarged partial views of FIG. 3;

FIG. 3c is a schematic partial view showing the portion of an auxiliary button when a portable electronic device is accommodated within the first embodiment;

FIG. 3d is a schematic cross-sectional view taken along a line A-A of FIG. 3;

FIG. 4 is a schematic illustration showing the outlook after the first embodiment is combined;

FIG. 5 is a decomposed schematic illustration showing a second embodiment of the invention;

FIG. 6 is a decomposed schematic illustration showing the second embodiment of the invention at another viewing angle;

FIG. 7 is a pictorial view showing a resilient frame of the second embodiment;

FIGS. 7a and 7b are enlarged partial views of FIG. 7;

FIG. 7c is a schematic partial view showing an auxiliary button when the portable electronic device is accommodated within the second embodiment;

FIG. 7d is a schematic cross-sectional view taken along a line B-B of FIG. 7; and

FIG. 8 is a schematic illustration showing the outlook after the second embodiment is combined.

### DETAILED DESCRIPTION OF THE PREFERRED EMBODIMENTS

At present, the most popular portable electronic devices include a tablet computer and a smart phone. This product (portable electronic device) may be operated through a touch screen, and has the auxiliary function key and jack, which are mostly disposed on the circumference of the portable electronic device. Thus, this invention provides an integrally formed waterproof resilient material mounted around the circumference of the portable electronic device to form an integral waterproof design and enhance the convenience in use. In the following, the tablet computer and the smart phone serve as embodiments to be described with reference to the accompanying drawings.

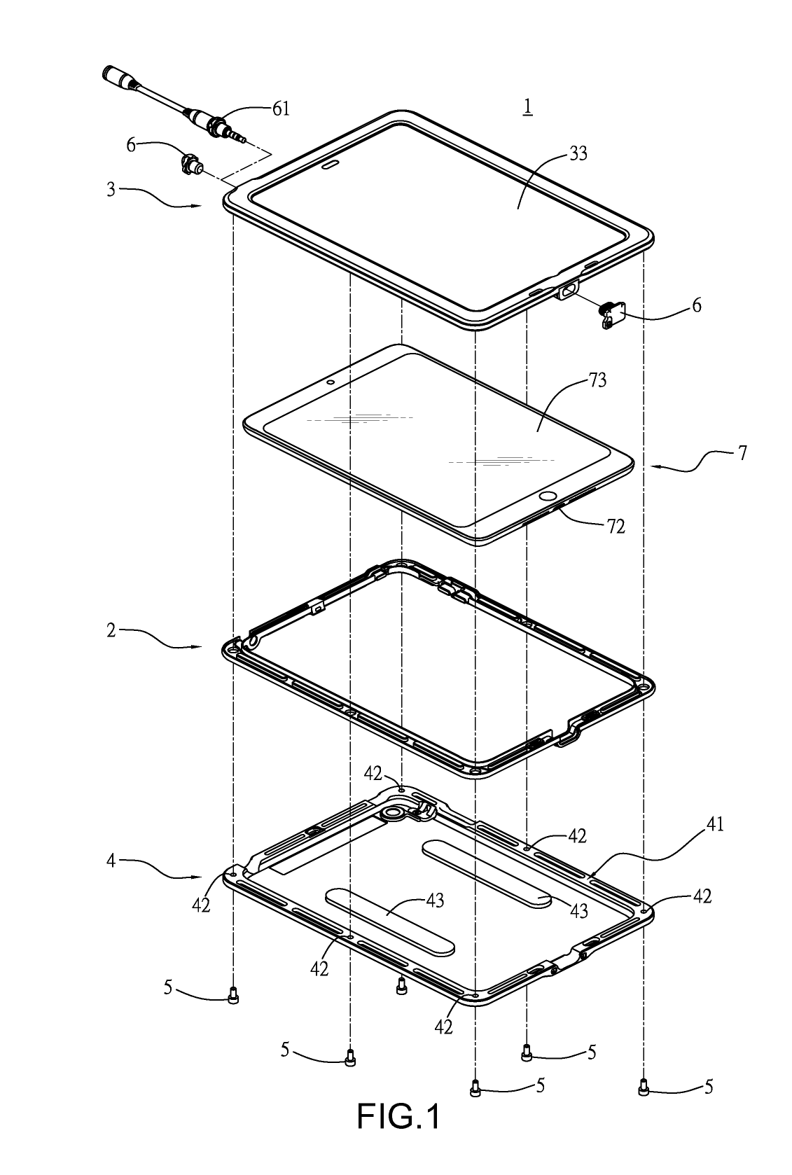

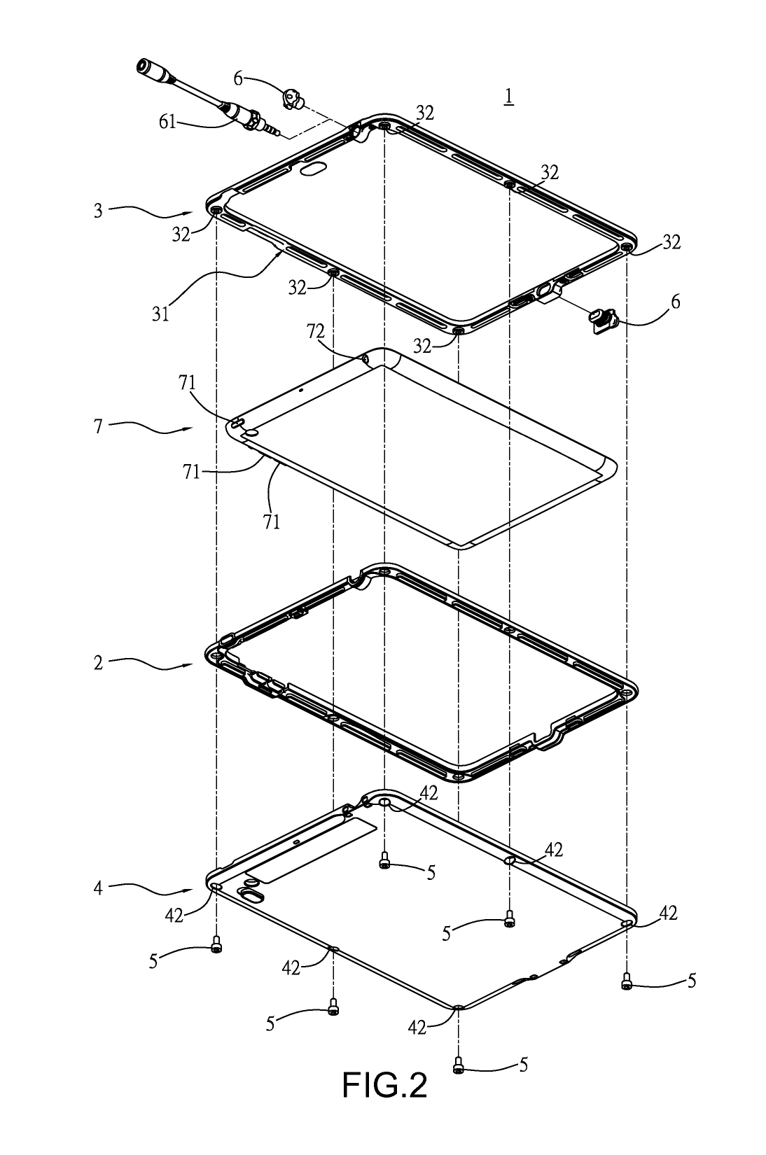

FIGS. 1 and 2 are exploded views showing the first embodiment of the invention. A waterproof container 1 of this embodiment is for accommodating a portable electronic device (tablet computer) 7, and mainly includes a first housing 3, a resilient frame 2, a second housing 4 and a plurality of screw members 5. The resilient frame 2 is disposed between the first housing 3 and the second housing 4, composed of a resilient material, and in the form of a polygonal ring structure according to the shape of the portable electronic device 7. In the embodiment of the invention, the resilient frame 2 is a rectangular ring surrounding the portable electronic device 7, and located at the position corresponding to its circumferential function key 71 or jack 72. The first housing 3 is annularly formed with a first combining portion 31, to be combined with a surface of the resilient frame 2, at the position corresponding to the resilient frame 2, while the second housing 4 is annularly formed with a second combining portion 41, to be combined with a bottom surface of the resilient frame 2, at the position corresponding to the resilient frame 2. Also, the first housing 3 and the second housing 4 have a plurality of first screwing portions 32 and a plurality of second screwing portions 42, to be screwed by the screw members 5, at corresponding positions, respectively. The first housing 3 and the second housing 4 are combined together, and the resilient frame 2 disposed between the first housing 3 and the second housing 4 is tightly clamped to form the waterproof container structure.

In this embodiment, after the first housing 3, the resilient frame 2 and the second housing 4 are combined together by the screw members 5, the inner sides thereof form a space capable of accommodating the portable electronic device 7. The first housing 3 is formed with a transparent panel 33 at the position corresponding to a surface touch screen 73 of the portable electronic device 7, while the inner surface of the second housing 4 is formed with at least one resilient pad 43. When the portable electronic device 7 is accommodated therein, the resilient pad 43 pushes against the backside of the portable electronic device 7, so that the surface touch screen 73 of the portable electronic device 7 may be in close contact with the transparent panel 33 of the first housing 3. Therefore, the user can press or touch the transparent panel 33 to operate the touch screen 73.

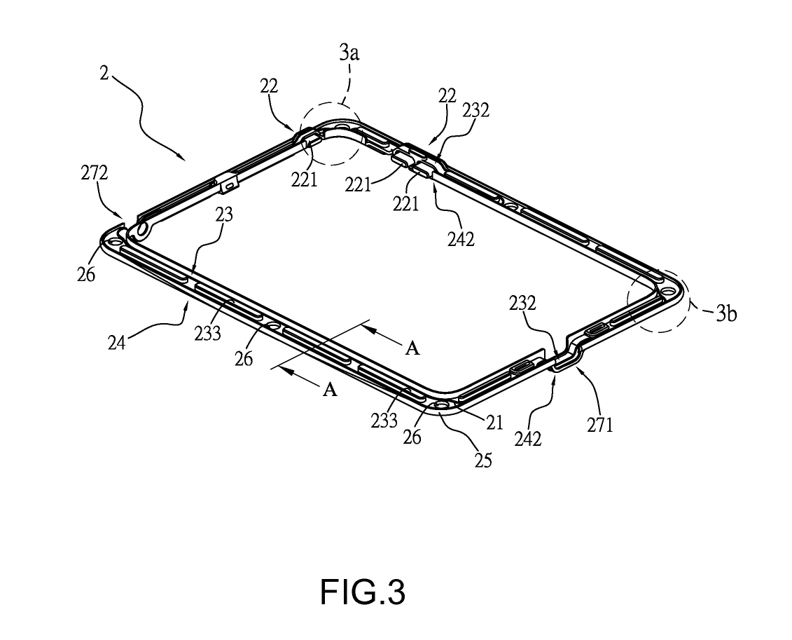

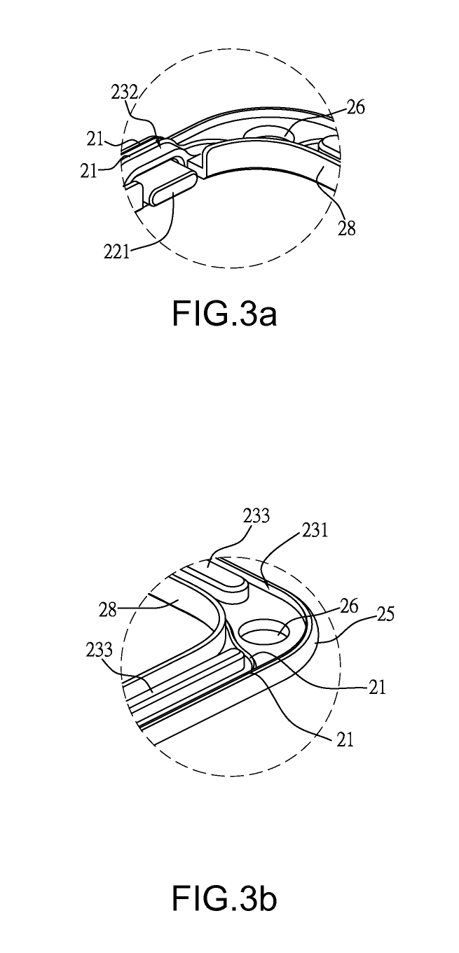

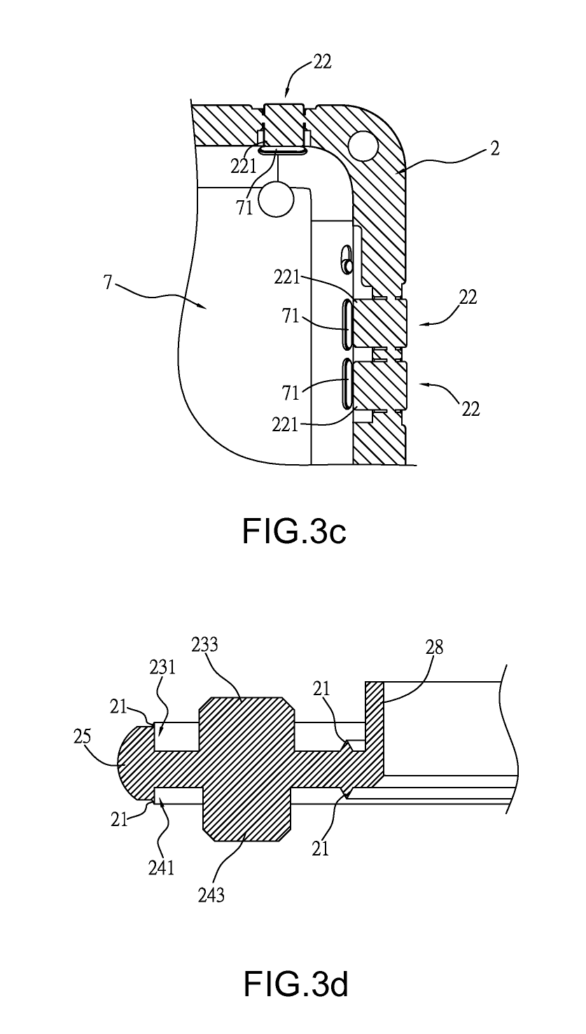

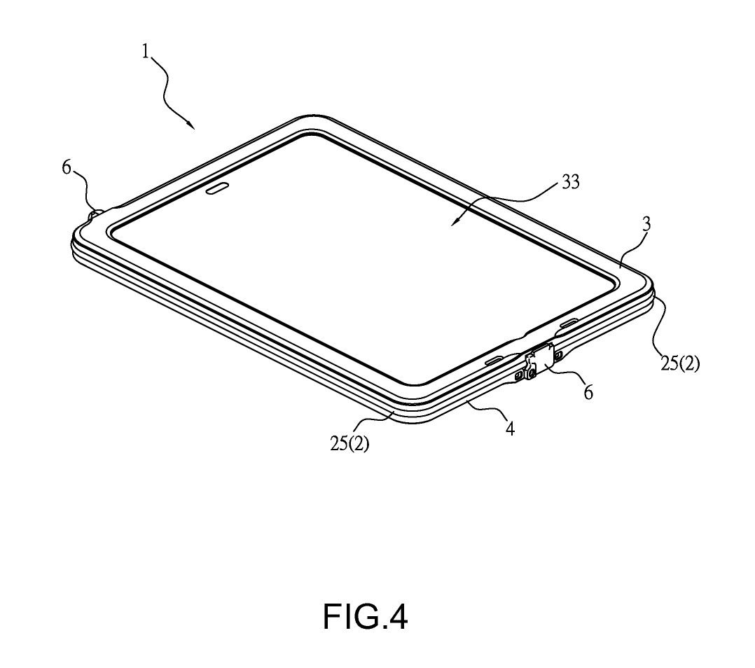

Referring to FIGS. 3 and 3a to 3d, the resilient frame 2 of this embodiment surrounds the portable electronic device 7, and is formed with an auxiliary button 22, an opening 271 or a hole 272 at the positions corresponding to the function key 71 and the jack 72 of the portable electronic device 7. The resilient frame 2 is inwardly and projectingly formed with a button projection 221 on the inner side of the auxiliary button 22, and the button projection 221 can be pressed to push against the function key 71 of the portable electronic device 7 (see FIG. 3c). The opening 271 or the hole 272 formed on the resilient frame 2 may be closed by a waterproof plug 6. When the user wants to use the function of the jack 72 (e.g., charging, connecting to an earphone, or the like), the user can use the function by only pulling out the waterproof plug 6 at the corresponding position without disassembling the waterproof container 1 and taking out the portable electronic device 7. Furthermore, as shown in FIGS. 1 and 2, the user may also directly insert an insert 61 having the waterproof plug so that the portable electronic device can be used in the water.

A plurality of through holes 26 corresponding to the positions of the first screwing portions 32 or the second screwing portions 42 may also be formed between the surface and the bottom surface of the resilient frame 2 of this embodiment, so that the screw members 5 can pass through the through holes 26. Also, the outer side of the resilient frame 2 is projectingly formed with a protection edge 25 (see also FIG. 4), wherein the protection edge 25 can surround the resilient frame 2 in a continuous or discontinuous manner. In this embodiment, the protection edge 25 is discontinuously disposed (cutoffs are formed at the positions of the auxiliary button 22 and the waterproof plug 6), so that the effect of buffering the external force can be achieved.

The surface or the bottom surface of the resilient frame 2 is formed with the structure of convex edge/concave edge 232, 242 at the position corresponding to the auxiliary button 22, the opening 271 or the hole 272. Thus, when the resilient frame 2 is combined with the first housing 3 and the second housing 4, the limiting effect can be generated. In addition, the surface and the bottom surface of the resilient frame 2 are formed with a first limit structure 23 and a second limit structure 24, respectively, and the shapes of the first combining portion 31 and the second combining portion 41 relatively match with those of the first limit structure 23 and the second limit structure 24, respectively. In addition to the above-mentioned structure of the convex edge/concave edge 232, 242, the first limit structure 23 and the second limit structure 24 of this embodiment further include the followings structures. The first limit structure 23 additionally includes a first limit slot 231 formed between the protection edge 25 and the surface of the resilient frame 2, and a plurality of limit projections 233 projectingly formed on the surface of the resilient frame 2. Similarly, the second limit structure 24 includes a second limit slot 241 formed between the protection edge 25 and the bottom surface of the resilient frame 2, and a plurality of limit projections 243 projectingly formed on the bottom surface of the resilient frame 2.

The surface or the bottom surface of the resilient frame 2 of this embodiment is further projectingly formed with a waterproof land 21, which may be surroundingly disposed on the surface or the bottom surface of the resilient frame 2 in a continuous or discontinuous manner so that the multiple better waterproof effects can be obtained. As shown in FIGS. 3a, 3b and 3d, the surface and the bottom surface of the resilient frame 2 of this embodiment have two waterproof lands 21, respectively. The waterproof lands 21 are surroundingly disposed in the continuous manner without gaps due to the structure of the convex edge/concave edge 232, 242, and surround the inner sides and the outer sides of the through holes 26, wherein the inner side represents one side close to the portable electronic device 7, so that the optimum waterproof effect is achieved. Furthermore, in this embodiment, the inner surface of the resilient frame 2 is upwardly extended with a buffer pad 28 for assisting in fixing the horizontal position of the portable electronic device 7 and enhancing the impact-resisting ability.

The above-identified description relates to the aspect that the waterproof container 1 of the invention is applied to the portable electronic device (tablet computer) 7. In the following, another frequently seen aspect of the portable electronic device (smart phone) 7 will be described in the following.

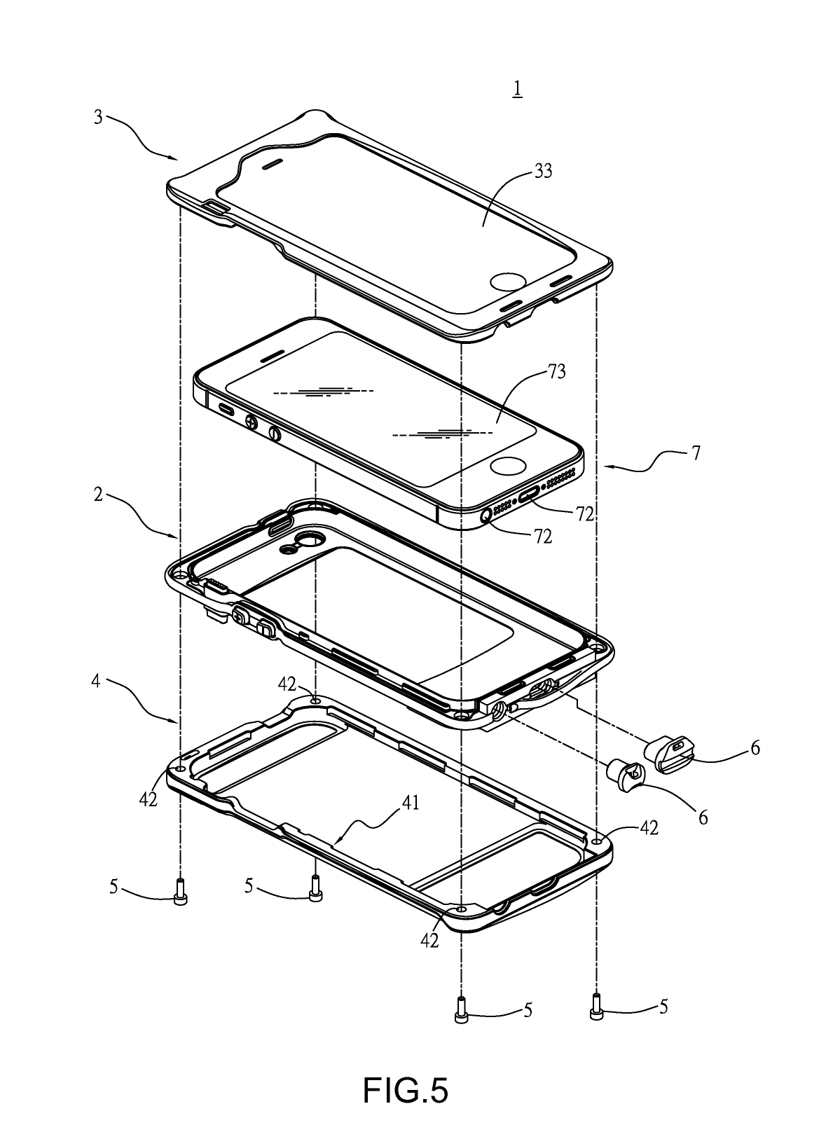

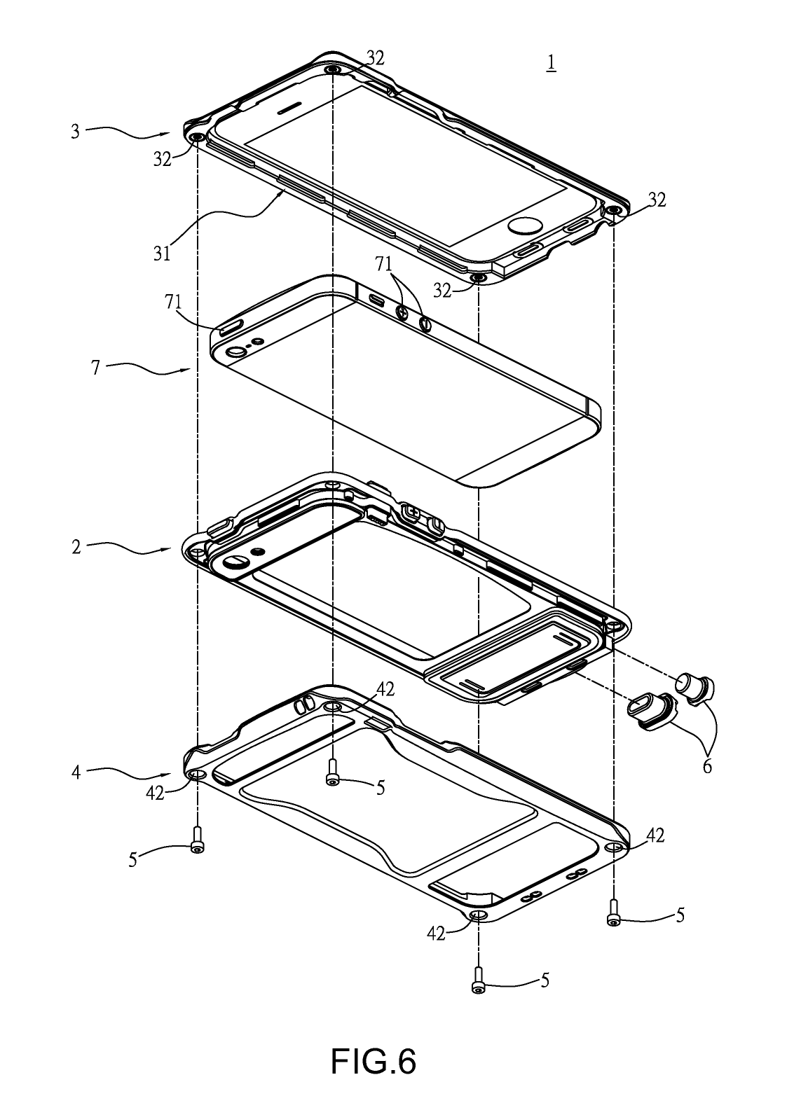

As shown in FIGS. 5 and 6, the waterproof container 1 of this embodiment, similar to the previous embodiment, is for accommodating the portable electronic device (smart phone) 7, wherein the main members include a first housing 3, a resilient frame 2, a second housing 4 and a plurality of screw members 5. The resilient frame 2 is a rectangular ring composed of a waterproof resilient material, and is for surrounding the portable electronic device 7 and disposed between the first housing 3 and the second housing 4. The first housing 3 is annularly formed with a first combining portion 31, to be combined with the surface of the resilient frame 2, at the position corresponding to the resilient frame 2. Similarly, the second housing 4 is annularly formed with a second combining portion 41, to be combined with the bottom surface of the resilient frame 2, at the position corresponding to the resilient frame 2. The first housing 3 and the second housing 4 are formed with a plurality of first screwing portions 32 and a plurality of second screwing portions 42, to be screwed by the screw members 5, at corresponding positions, respectively. The first screwing portions 32 and the second screwing portions 42 are to be screwed by the screw members 5, so that the first housing 3 and the second housing 4 are combined together to tightly clamp the resilient frame 2 disposed therebetween and the waterproof container structure is formed.

After the first housing 3, the resilient frame 2 and the second housing 4 are combined together by the screw members 5, the inner sides of the combination thereof form a space capable of accommodating the portable electronic device 7. The first housing 3 has a transparent panel 33 at the position corresponding to the surface touch screen 73 of the portable electronic device 7, while the inner surface of the resilient frame 2 is inwardly extended to form a resilient pad 281. When the portable electronic device 7 is accommodated therein, the resilient pad 281 is disposed between the backside of the portable electronic device 7 and the inner surface of the second housing 4. The resilient pad 281 pushing against the backside of the portable electronic device 7 and the second housing 4 makes the surface touch screen 73 of the portable electronic device 7 be able to be in close contact with the transparent panel 33 of the first housing 3, so that the user can press or touch the transparent panel 33 to operate the touch screen 73.

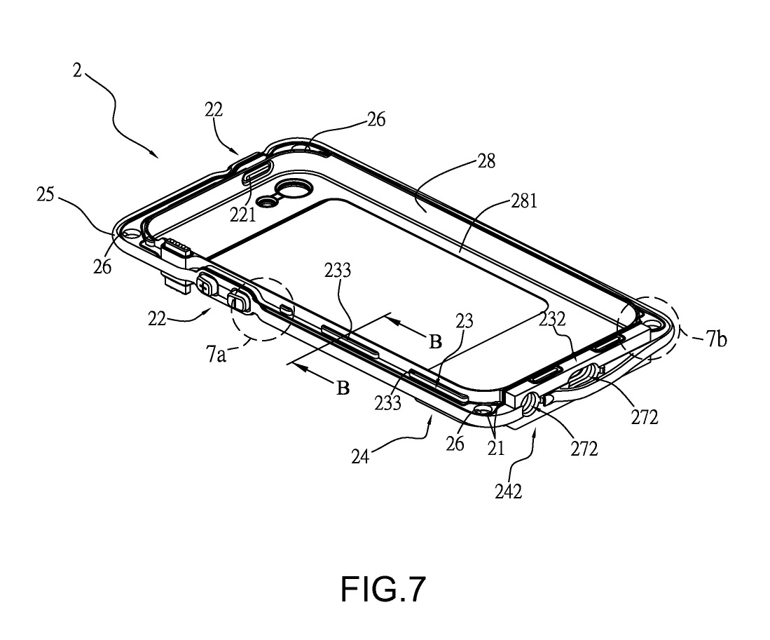

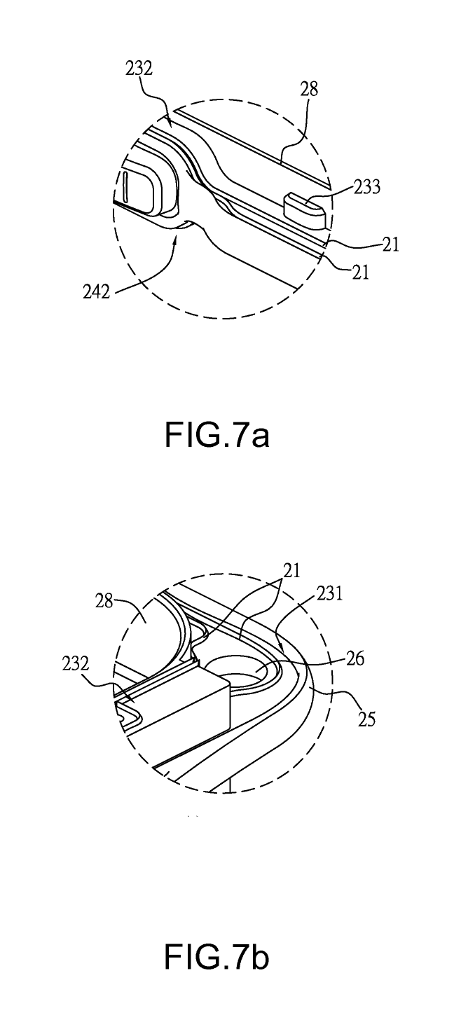

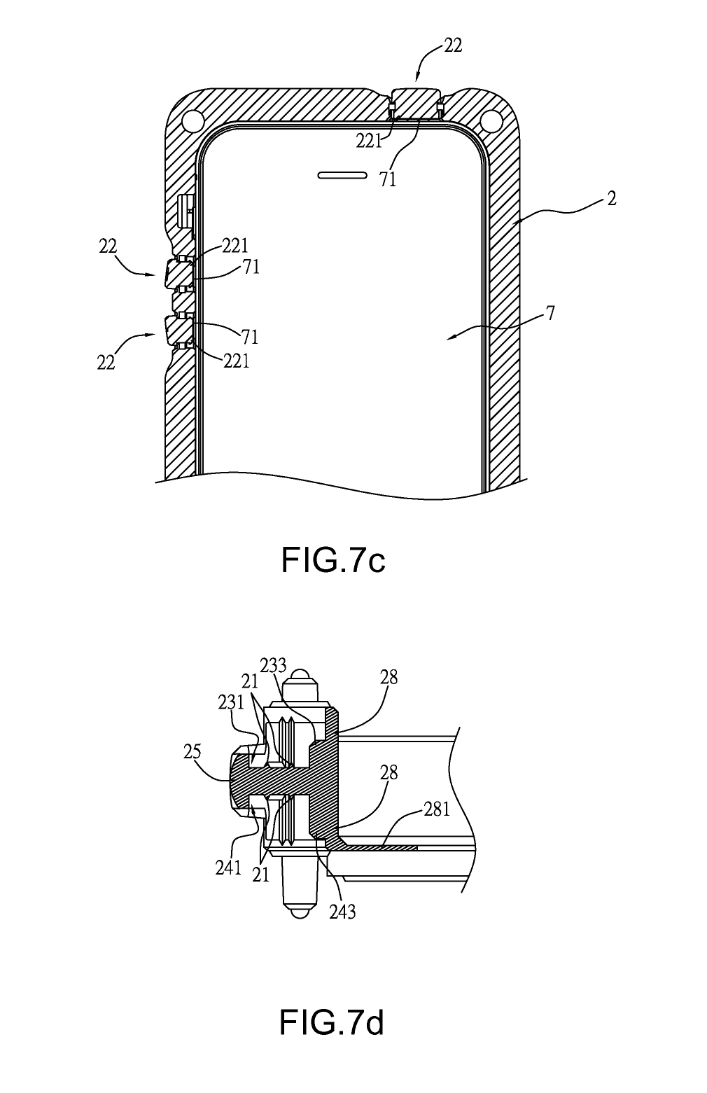

Referring to FIGS. 7 and 7a to 7d, the resilient frame 2 has auxiliary buttons 22 or hole 272 at positions corresponding to the function keys 71 and the jacks 72 of the portable electronic device 7. The inner side of the resilient frame 2 at the auxiliary button 22 is inwardly and projectingly formed with a button projection 221. The user can press the function key 71 of the portable electronic device 7 through the button projection 221 pushing against the function key 71 (see FIG. 7c). The hole 272 formed on the resilient frame 2 may be closed by the waterproof plug 6. When the user wants to directly use the function of the jack 72, he or she only needs to remove the waterproof plug 6 without repeating the step of disassembling or screwing, and this is advantageous to the enhancement of the convenience in use.

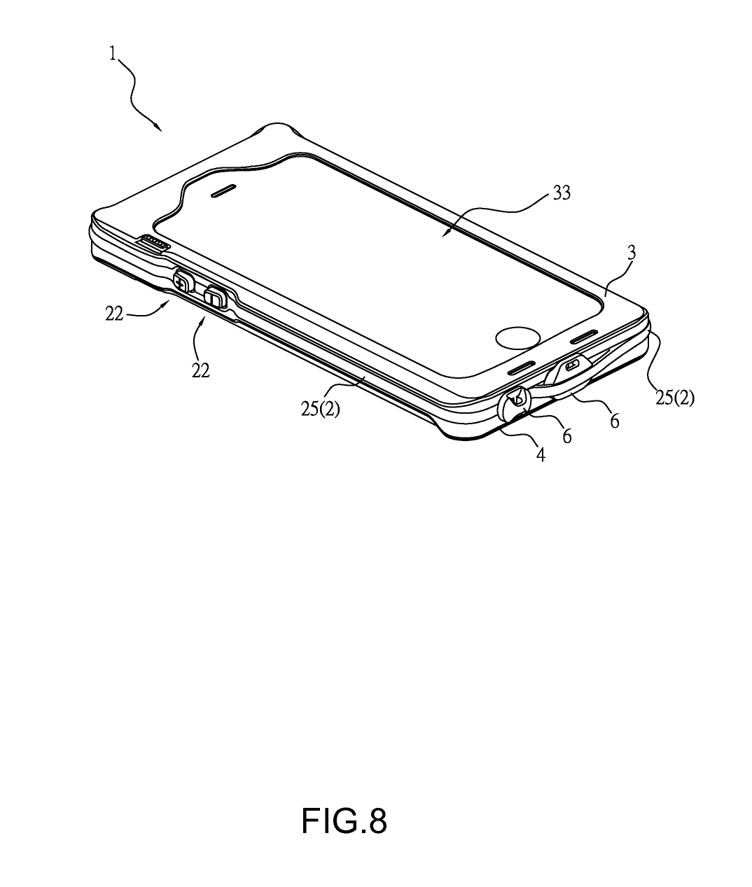

A plurality of through holes 26, corresponding to the positions of the first screwing portions 32 or the second screwing portions 42, may also be formed between the surface and the bottom surface of the resilient frame 2 of the second embodiment, so that the screw members 5 can pass through the through holes 26. Also, the outer side of the resilient frame 2 is projectingly formed with a protection edge 25 (see also FIG. 8), wherein the protection edge 25 may surround the outer side of the resilient frame 2 in a continuous or discontinuous manner. In this embodiment, the protection edge 25 may also be disposed in a discontinuous manner (cutoffs are formed at the positions of the auxiliary button 22 and the waterproof plug 6), so that the effect of buffering the external force can be achieved.

The position of the surface or the bottom surface of the resilient frame 2 corresponding to the auxiliary button 22 or the hole 272 is formed with the structure of the convex edge/concave edge 232, 242. Accordingly, when the resilient frame 2 is combined with the first housing 3 and the second housing 4, the limiting effect can be generated. In addition, the surface and the bottom surface of the resilient frame 2 are formed with the first limit structure 23 and the second limit structure 24, respectively, and the shapes of the first combining portion 31 and the second combining portion 41 relatively match with those of the first limit structure 23 and the second limit structure 24, respectively. In addition to the structure of the convex edge/concave edge 232, 242, the first limit structure 23 and the second limit structure 24 of this embodiment additionally include the following structures. The first limit structure 23 additionally includes a first limit slot 231 formed between the protection edge 25 and the surface of the resilient frame 2, and a plurality of limit projections 233 projectingly formed on the surface of the resilient frame 2. Similarly, the second limit structure 24 includes a second limit slot 241 formed between the protection edge 25 and the bottom surface of the resilient frame 2, and a plurality of limit projections 243 projectingly formed on the bottom surface of the resilient frame 2.

Furthermore, the surface and the bottom surface of the resilient frame 2 are projectingly formed with waterproof lands 21, as shown in FIGS. 7a, 7b and 7d. The surface and the bottom surface of the resilient frame 2 of this embodiment are also projectingly formed with two waterproof lands 21, respectively. The waterproof lands 21 are surroundingly disposed in a continuous manner and surround the inner sides and the outer sides of the through holes 26, respectively. One of the waterproof lands 21 surrounds the inner side of the through hole 26 (the one side close to the portable electronic device), and the other one of the waterproof lands 21 surrounds the outer sides of the through holes 26, so that the multiple waterproof properties are formed to achieve the optimum waterproof effect. Furthermore, the inner surface of the resilient frame 2 of this embodiment is extended upwardly and downwardly to form buffer pads 28 to assist in fixing the horizontal position of the portable electronic device 7, and to enhance the ability of resisting the impact. The downwardly extended buffer pad 28 is further inwardly extended to form the resilient pad 281 to assist in fixing the vertical position of the portable electronic device 7.

To sum up, compared with the conventional waterproof container structure, the waterproof container of the invention indeed has the better pressure resisting property, and also has the effects of mass production integration and facilitating the convenience of the user operation. So, the invention as filed satisfies the novelty and the inventive step.

New characteristics and advantages of the invention covered by this document have been set forth in the foregoing description. It is to be expressly understood, however, that the drawings are for the purpose of illustration only and are not intended as a definition of the limits of the invention. Changes in methods, shapes, structures or devices may be made in details without exceeding the scope of the invention by those who are skilled in the art. The scope of the invention is, of course, defined in the language in which the appended claims are expressed.

1. A waterproof container for accommodating a portable electronic device, the waterproof container comprising:
a resilient frame, which is a polygonal ring, disposed at a horizontal position corresponding to the portable electronic device, and for surrounding a circumference of the portable electronic device;
a first housing, which is disposed above the resilient frame and annularly formed with a first combining portion to be combined with a surface of the resilient frame, and has a plurality of first screwing portions;
a second housing, which is disposed below the resilient frame, annularly formed with a second combining portion, to be combined with a bottom surface of the resilient frame, and has a plurality of second screwing portions at positions corresponding to the first screwing portions; and
a plurality of screw members for screwing the first screwing portions to the second screwing portions, so that the first housing, the resilient frame and the second housing are combined together, a relative position between the first housing and the second housing is fixed, and the first housing and the second housing can tightly clamp the resilient frame to achieve a waterproof effect.

2. The waterproof container according to claim 1, wherein the resilient frame further has at least one auxiliary button, which is projectingly formed with a button projection for pushing against a function key on the circumference of the portable electronic device at a position corresponding to an inner surface of the resilient frame.

3. The waterproof container according to claim 1, wherein the resilient frame is further projectingly formed with at least one waterproof land surroundingly disposed on the surface or the bottom surface of the resilient frame in a continuous or discontinuous manner.

4. The waterproof container according to claim 2, wherein the resilient frame is further projectingly formed with at least one waterproof land surroundingly disposed on the surface or the bottom surface of the resilient frame in a continuous or discontinuous manner.

5. The waterproof container according to claim 4, wherein a plurality of through holes is further formed between the surface and the bottom surface of the resilient frame, and the through holes, through which the screw members pass, are disposed at the positions corresponding to the first screwing portions.

6. The waterproof container according to claim 5, wherein the through holes are disposed on an outer side of the waterproof land.

7. The waterproof container according to claim 6, wherein the resilient frame further has another waterproof land surrounding outer sides of the through holes.

8. The waterproof container according to claim 1, wherein the resilient frame further has a protection edge surroundingly disposed on an outer side of the resilient frame in a continuous or discontinuous manner.

9. The waterproof container according to claim 8, wherein the surface of the resilient frame has a first limit structure, and a shape of the first combining portion relatively matches with the first limit structure.

10. The waterproof container according to claim 9, wherein the first limit structure comprises a first limit slot formed between the protection edge and the surface of the resilient frame, and a convex edge or a concave edge of the resilient frame formed at a position corresponding to a function key or a jack on the circumference of the portable electronic device.

11. The waterproof container according to claim 10, wherein the bottom surface of the resilient frame is formed with a second limit structure, a shape of the second combining portion relatively matches with the second limit structure, and the second limit structure comprises a second limit slot formed between the protection edge and the bottom surface of the resilient frame, and the convex edge or the concave edge of the resilient frame formed at the position corresponding to the function key or the jack on the circumference of the portable electronic device.

12. The waterproof container according to claim 11, further comprising at least one waterproof plug for closing an opening or a hole formed on the resilient frame at the position corresponding to the jack on the circumference of portable electronic device.

13. The waterproof container according to claim 12, wherein each of the first limit structure and the second limit structure further comprises a plurality of limit projections.

14. The waterproof container according to claim 13, wherein the first housing further has a transparent panel, which is disposed at a position corresponding to a surface touch screen of the portable electronic device, and for covering the surface touch screen of the portable electronic device when the portable electronic device is accommodated.

15. The waterproof container according to claim 14, wherein an inner surface of the resilient frame is further upwardly or downwardly extended with a buffer pad.

16. The waterproof container according to claim 14, wherein an inner side of the second housing further has at least one resilient pad for pushing against a backside of the portable electronic device.

17. (canceled)
